(19) United States
(12) Patent Application Publication
(10) Pub. No.: US 2021/0134870 A1
(43) Pub. Date: May 6, 2021

(54) LENS ARRAY, IMAGING DEVICE, AND METHOD OF MANUFACTURING LENS ARRAY

(71) Applicant: OLYMPUS CORPORATION, Tokyo (JP)

(72) Inventor: Yasuhiro MIYAZAKI, Tokyo (JP)

(73) Assignee: OLYMPUS CORPORATION, Tokyo (JP)

(21) Appl. No.: 17/128,900

(22) Filed: Dec. 21, 2020

Related U.S. Application Data
(63) Continuation of application No. PCT/JP2018/023855, filed on Jun. 22, 2018.

(51) Int. Cl. H01L 27/146; G02B 3/00; G02B 7/02

(52) U.S. Cl. CPC H01L 27/14627; G02B 3/0037; H01L 27/14605; G02B 3/0012; H01L 27/14685; G02B 7/021

(57) ABSTRACT

A lens array includes a plurality of lens parts arranged on a curved surface in a two-dimensional array. Each of the plurality of lens parts includes: a base part provided with a tapered side surface having an outer diameter that becomes smaller in a height direction away from the curved surface; and an apex part located on the base part and having a lens surface. There is an angular difference Δθ between height directions of two adjacent lens parts of the plurality of lens parts. The angular difference Δθ is smaller than an amount double a taper angle θ of the side surface of each of the two adjacent lens parts.

### CROSS-REFERENCE TO RELATED APPLICATIONS

This application is based upon and claims the benefit of priority from International Application No. PCT/JP2018/023855, filed on Jun. 22, 2018, the entire content of which is incorporated herein by reference.

### BACKGROUND OF THE INVENTION

### 1. Field of the Invention

The present invention relates to a lens array, an imaging device, and a method of manufacturing a lens array.

### 2. Description of the Related Art

A technology is known whereby the light receiving efficiency of an imaging device is enhanced by using a lens array in which microlenses each having a diameter substantially as large as the pixel size are arranged on the imaging surface of an imaging device in an array so as to be in alignment with the pixels. However, a problem could arise in that, when an incident light beam from an object is incident on the imaging surface at a large angle, the light beam incident on each microlens leaks to an adjacent pixel, producing a crosstalk between pixels and reducing the image quality. A technology of providing a light absorption part for absorbing incident light between adjacent microlenses is proposed to solve the problem (see, for example, patent literature 1).

[Patent literature 1] JP2017-116633

An attempt to prevent a crosstalk by absorbing a portion of the incident light beam results in the amount of light beam entering the pixel being reduced, which may lead to reduction in image quality.

### SUMMARY OF THE INVENTION

The present invention addresses the above-described issue, and an illustrative purpose of an embodiment thereof is to provide a lens array in which a crosstalk between adjacent pixels is suppressed.

An embodiment of the present invention relates to a lens array including a plurality of lens parts arranged on a curved surface in a two-dimensional array. Each of the plurality of lens parts includes: a base part provided with a tapered side surface having an outer diameter that becomes smaller in a height direction away from the curved surface, and an apex part located on the base part and having a lens surface. There is an angular difference between height directions of two adjacent lens parts of the plurality of lens parts, and the angular difference is smaller than an amount double a taper angle of the side surface of each of the two adjacent lens parts.

Another embodiment of the present invention relates to an imaging device. The imaging device includes: a base having a curved surface; a plurality of pixels arranged on the curved surface of the base in a two-dimensional array; and the lens array, wherein, on each of the plurality of pixels, a corresponding lens part of the lens array is located.

Another embodiment of the present invention relates to a method of manufacturing a lens array including a plurality of lens parts arranged on a curved surface in a two-dimensional array. Each of the plurality of lens parts includes: a base part having a tapered side surface having an outer diameter that becomes smaller in a height direction away from the curved surface; and an apex part located on the base part and having a lens surface. Each of the plurality of lens parts is formed by stacking a hardened layer formed by irradiating a photocrosslinkable material ejected from a molding head with light.

Optional combinations of the aforementioned constituting elements, and implementations of the invention in the form of methods, apparatuses, and systems may also be practiced as additional modes of the present invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a cross-sectional view schematically showing an imaging device according to an embodiment;

FIG. 2 is a cross-sectional view showing a configuration of the lens array according to an embodiment in detail;

FIG. 3 schematically shows a method of manufacturing the lens array according to an embodiment;

FIG. 4 schematically shows a method of manufacturing the lens array according to an embodiment; and

FIGS. 5A and 5B schematically show a method of manufacturing the lens array according to an embodiment.

### DETAILED DESCRIPTION OF THE INVENTION

The invention will now be described by reference to the preferred embodiments. This does not intend to limit the scope of the present invention, but to exemplify the invention.

A detailed description will be given of embodiments of the present invention with reference to the drawings. In the explanations of the figures, the same elements shall be denoted by the same reference numerals, and duplicative explanations will be omitted appropriately. The configuration described below is by way of example only and does not limit the scope of the present invention.

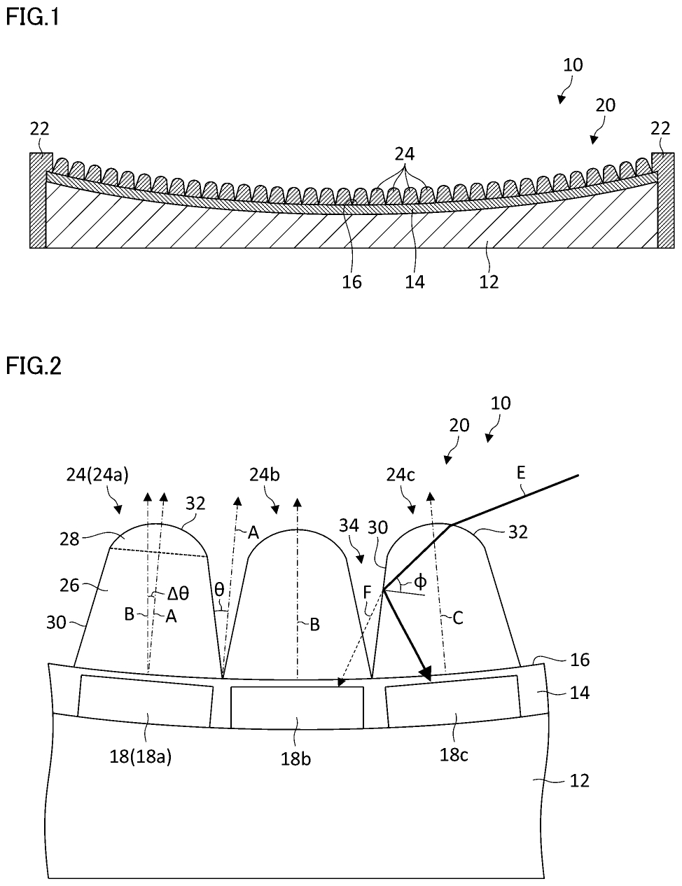

FIG. 1 is a cross-sectional view schematically showing an imaging device 10 according to an embodiment. The imaging device 10 includes a base 12, a photoelectric conversion layer 14, and a lens array 20. The imaging device 10 is a so-called CCD sensor or a CMOS sensor. The imaging device 10 converts light incident on each pixel of the photoelectric conversion layer 14 into an electric signal to generate captured imaged data. An imaging surface 16 is the surface of the photoelectric conversion layer 14. The imaging surface 16 is a concave curved surface. By configuring the imaging surface 16 to be a concave curved surface, impact of field curvature, etc. caused by an imaging optical system for focusing imaging light on the imaging surface 16 is suppressed, and a high-quality image can be captured even if an imaging optical system having a relatively simple configuration is used.

The lens array 20 includes a frame 22 and a plurality of lens parts 24. The lens array 20 is a so-called microlens array, and the plurality of lens parts 24 are arranged in a two-dimensional array. The plurality of lens parts 24 are provided on the imaging surface 16 that is a concave curved surface and are arranged at positions aligned with the respective pixels of the photoelectric conversion layer 14. The frame 22 is provided at the outer circumference of the plurality of lens parts 24. The frame 22 can be attached to the side surface of the base 12. The frame 22 positions the plurality of lens parts 24 in precise alignment with the respective pixels of the photoelectric conversion layer 14.

FIG. 2 is a cross-sectional view showing a configuration of the lens array 20 according to an embodiment in detail and is an enlarged view of a portion of FIG. 1. FIG. 2 shows three lens parts 24a, 24b, and 24c respectively arranged above corresponding pixels 18a, 18b, and 18c (also generically referred to as pixels 18) of the photoelectric conversion layer 14.

Red (R), green (G), and blue (B) color filters may be provided between the lens parts 24 and the pixels 18 (not shown). For example, a red color filter may be provided between the first lens part 24a and the first pixel 18a, a green color filter may be provided between the second lens part 24b and the second pixel 18b, and a blue color filter may be provided between the third lens part 24c and the third pixel 18c.

Each lens part 24 includes a base part 26 and an apex part 28. The base part is a part in contact with the imaging surface 16 and has a tapered side surface 30 having an outer diameter that becomes smaller in the height direction away from the imaging surface 16. The base part 26 has, for example, a shape of a truncated cone or a truncated pyramid or has a similar shape. The apex part 28 is a part located on the base part 26 and has a lens surface 32 comprised of a convex curved surface.

The lens parts 24 are arranged on the imaging surface 16 that is a concave curved surface so that the height directions thereof, i.e., the directions orthogonal to the imaging surface 16 may differ. In other words, height directions A, B, and C of the plurality of lens parts 24a, 24b, and 24c, respectively, are not parallel to each other. As a result, there is an angular difference Δθ between the height directions A and B of the two adjacent lens parts 24a and 24b. The angular difference Δθ between the height directions A and B of the two adjacent lens parts 24a and 24b is smaller than an amount double a taper angle θ of the side surface 30 of the two adjacent lens parts 24a and 24b. Stated otherwise, the taper angle θ of the side surface 30 of the two adjacent lens parts 24a and 24b is equal to or greater than an amount double the angular difference Δθ between the height directions A and B of the two adjacent lens parts 24a and 24b. The taper angle θ of the side surface 30 is defined as an angle between the height direction of the lens part 24 and the side surface 30. The embodiment is non-limiting as to the value of the taper angle θ, but the taper angle may be about 10°-25°.

A gap 34 between the two adjacent lens parts 24 is, for example, air. Therefore, the refractive index of the medium in the gap 34 between the two adjacent lens parts 24 is smaller than the refractive index of the lens parts 24. The lens part 24 is made of, for example, a resin material or a glass material that is transparent to visible light and has, for example, a refractive index not smaller than 1.3 and not greater than 1.4 for visible light. By configuring the refractive index of the gap 34 between the two adjacent lens parts 24 to be smaller than the refractive index of the lens parts 24, the light inside the lens parts 24 can be effectively contained inward of the side surface 30 of the lens parts 24. The gap 34 between the two adjacent lens parts 24 may be filled with a material having a lower refractive index than the material of the lens parts 24.

According to this embodiment, each lens part 24 of the lens array 20 has the tapered side surface 30 and the lens surface 32 so that much of the light incident on the lens array 20 can be guided to the respective pixels 18 of the photoelectric conversion layer 14. In the case a light beam E is incident diagonally with respect to the height directions A-C of the respective lens parts 24, the light beam E entering the interior of the lens part 24 via the lens surface 32 is incident on the tapered side surface 30 at a relatively large incidence angle ψ. As compared with the case where the side surface 30 is not tapered and the side surface 30 is perpendicular to the imaging surface 16, the incidence angle ψ of the light beam E at the side surface 30 may be larger. As a result, much of the light beam E can be contained within the interior of the lens part 24. In most cases, the light beam E can be totally reflected at the side surface 30 and guided to the corresponding pixel 18. This can guide much of the light to the respective pixels 18 of the photoelectric conversion layer 14. Since the light beam E is prevented from passing through the side surface 30 of the lens part 24c and entering the adjacent lens part 24b, cross talk between adjacent pixels is suitably suppressed.

A description will now be given of a method of manufacturing the imaging device 10, and, in particular, a method of forming the lens array 20 on a curved surface. Ink-jet 3D printing (so-called 3D printing) technology can be used to manufacture the lens array 20. A description will be given of 1) a method of forming the lens part 24 directly on a curved surface and 2) a method of forming the lens part 24 on a flat surface and then curving the flat surface.

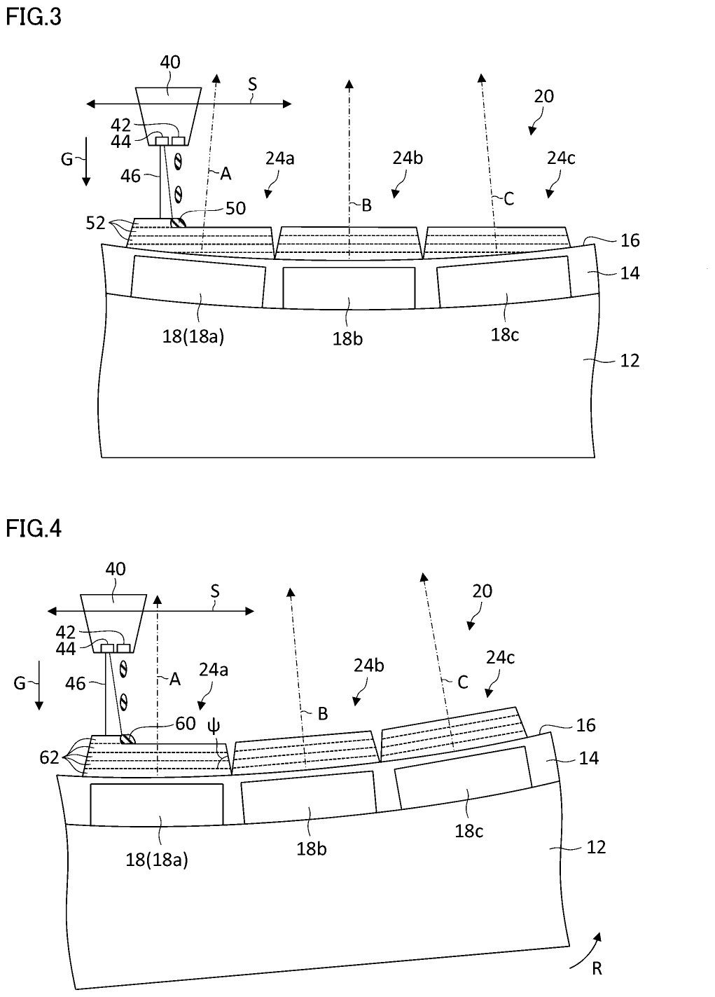

FIG. 3 schematically shows a method of manufacturing the lens array 20 according to an embodiment. First, the photoelectric conversion layer 14 in which the imaging surface 16 is a concave curved surface is formed on the base 12. A plurality of hardened layers 52 are then stacked on the imaging surface 16 to form the respective lens parts 24a-24c.

The hardened layer 52 is formed by irradiating a photocrosslinkable material 50 ejected from a molding head 40 with a hardening light 46 such as ultraviolet light. The molding head 40 includes an ejection unit 42 for ejecting the photocrosslinkable material 50 and an irradiation unit 44 for irradiating the ejected photocrosslinkable material 50 with the hardening light 46. The hardened layer 52 is formed by driving the molding head 40 for a scan above a reference plane 16 in a direction of an arrow S, ejecting the photocrosslinkable material 50 to a portion where the lens 20 should be formed, and irradiating the portion with the hardening light 46 to harden the photocrosslinkable material 50. By stacking the hardened layers 52 formed in this way, the lens parts 24a-24c are formed. Further, the frame 22 shown in FIG. 1 can be formed by also forming a hardened layer at the outer circumference of the plurality of lens parts 24. By forming the frame 22 concurrently, misalignment of the lens parts 24 with the respective pixels 18 is suitably prevented.

In the method shown in FIG. 3, the orientation of the base 12 relative to the molding head 40 is fixed, and least one of the base 12 and the molding head 40 is moved for a scan in a direction indicated by an arrow S. Therefore, a direction of ejection G (e.g., the gravitational direction) of the photocrosslinkable material 50 from the molding head 40 and the height directions A-C of the respective lens parts 24a-24c are not necessarily parallel. For example, the direction of ejection G of the photocrosslinkable material 50 from the molding head 40 is parallel to the height direction B of the second lens part 24b shown at the center and is not parallel to the height directions A and C of the first lens part 24a and the third lens part 24c, respectively, shown to the left and to the right.

FIG. 4 shows a method of manufacturing the lens array 20 according to an embodiment different from the embodiment of FIG. 3 in that the orientation of the base 12 relative to the molding head 40 is changed during manufacturing. Referring to FIG. 4, the normal direction of the imaging surface 16 and the direction of ejection from the molding head 40 are aligned in areas where the respective lens parts 24a-24c should be formed, by rotating or tilting the base 12 in a direction of an arrow R during manufacturing of the lens array 20. In the case of stacking a hardened layer 62 to form the first lens part 24a, for example, the direction of ejection G of the photocrosslinkable material 60 from the molding head 40 and the height direction A in the area where the first lens part 24a should be formed are made parallel, by adjusting the orientation of the base 12 relative to the molding head 40.

In the case of the manufacturing method shown in FIG. 3, the orientation of the base 12 relative to the molding head 40 is fixed so that it is possible to manufacture the lens array 20 by using a plurality of molding heads 40 or a plurality of ejection units 42 concurrently. By ejecting the photocrosslinkable material 50 from the plurality of ejection units 42 arranged in a one-dimensional array or a two-dimensional array in parallel, the time required to manufacture the lens array 20 is reduced as compared with the case of using a single ejection unit 42.

In the case of the manufacturing method shown in FIG. 4, the orientation of the imaging surface 16 relative to the molding head 40 remains unchanged while the plurality of lens parts 24 are respectively formed so that the respective lens parts 24 have a common stacked shape. In other words, the lens array 20 can be formed by using molding data common to the respective lens parts 24. Also, an angle of inclination ψ of the side surface of the lens part 24 (e.g., the first lens part 24a) being manufactured and located immediately below the molding head 40 (to be more specific, an angle of inclination ψ of the side surface lateral to the plane of the hardened layer 62 with reference to the direction of ejection G) is prevented from becoming not less than 80° and not more than 90° (i.e., right angle or obtuse angle). When the taper angle θ of the side surface 30 of the lens part 24 is small (e.g., when the taper angle θ is about) 10°-15°, in particular, the angle of inclination ψ of the side surface is prevented from becoming larger than a certain value during manufacturing even if the curvature of the imaging surface 16 is large. If the angle of inclination ψ of the side surface with reference to the direction of ejection exceeds 90° and becomes an obtuse angle, the side surface will have a shape that bulges outward with reference to the gravitational direction G, with the result that it may be difficult to stack the hardened layer 62 properly. The angle of inclination ψ of the side surface of 80°-90° may also result in difficulty to form the side surface with high precision. According to the method of FIG. 4, difficulty of stacking the lens parts 24 is prevented and the lens parts 24 with high shape precision are formed, by changing the orientation of the molding head 40 relative to the base 12 depending on the area where each lens part 24 is formed.

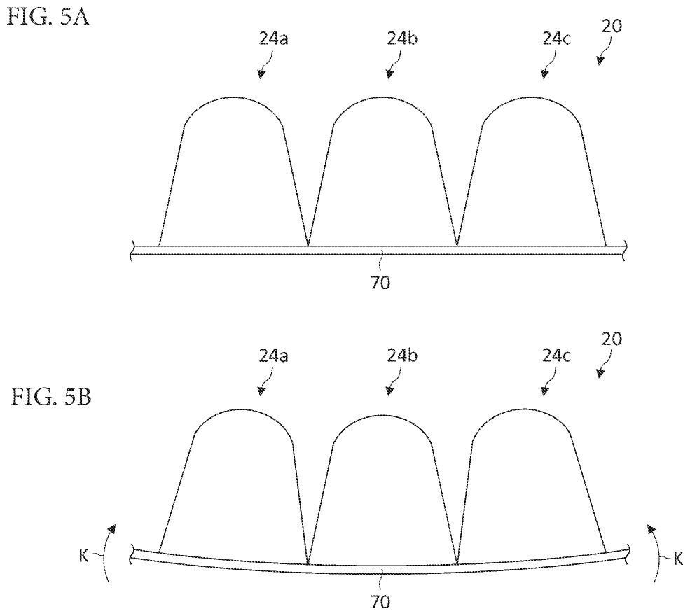

FIGS. 5A and 5B show a method of manufacturing the lens array 20 according to an embodiment and show a method of curving a base 70. First, the lens parts 24a-24c are formed on a flat base 70 as shown in FIG. 5A. Then, as shown in FIG. 5B, the base 70 is curved in a direction of an arrow K to arrange the respective lens parts 24a-24c on the concave curved surface. The lens parts 24a-24c shown in FIG. 5A can be formed by a similar 3D printing technology as used in the manufacturing method shown in FIG. 3 described above.

According to this embodiment, the lens array 20 is formed directly on the imaging surface 16 so that the positional precision between the respective pixels 18 arranged on the imaging surface 16 and the corresponding lens parts 24 is increased. Further, by integrally forming the frame 22 provided at the outer circumference of the plurality of lens parts 24 by 3D printing using the same material as used to form the lens parts 24, misalignment between the lens parts 24 and the frame 22 is prevented, and the positional precision of fixing the lens array 20 relative to the base 12 by using the frame 22 is increased.

The present invention has been described with reference to the embodiments but is not limited to the embodiments described above. Appropriate combinations or replacements of the features of the illustrated examples are also encompassed by the present invention. The embodiments may be modified by way of combinations, rearranging of the processing sequence, design changes, etc., based on the knowledge of a skilled person, and such modifications are also within the scope of the present invention.

In the embodiments described above, the lens array 20 is described as being formed directly on the imaging surface 16. In one variation, the imaging device 10 may be manufactured by forming the lens array 20 on a base having a curved shape corresponding to the imaging surface 16 and positioning the base on the imaging surface 16.

In the embodiments described above, the lens array 20 is described as being formed on the curved surface. In one variation, the aforementioned detail may be applied to the case of forming the lens array on a flat surface. In other words, the lens array according to the embodiments described above may be employed as the lens array for an ordinary imaging device having a flat imaging surface.

What is claimed is:

1. A lens array comprising a plurality of lens parts arranged on a curved surface in a two-dimensional array, wherein
each of the plurality of lens parts includes:
a base part provided with a tapered side surface having an outer diameter that becomes smaller in a height direction away from the curved surface, and an apex part located on the base part and having a lens surface, wherein
there is an angular difference between height directions of two adjacent lens parts of the plurality of lens parts, and the angular difference is smaller than an amount double a taper angle of the side surface of each of the two adjacent lens parts.

2. The lens array according to claim 1, wherein
the plurality of lens parts are arranged on the concave curved surface.

3. The lens array according to claim 1, wherein
a refractive index of a medium between two adjacent lens parts of the plurality of lens parts is smaller than a refractive index of a material of the plurality of lens parts.

4. The lens array according to claim 1, further comprising:
a frame provided at an outer circumference of the plurality of lens parts, wherein
the frame is made of the same material as the plurality of lens parts.

5. An imaging device comprising:
a base having a curved surface;
a plurality of pixels arranged on the curved surface of the base in a two-dimensional array; and
the lens array according to claim 1, wherein, on each of the plurality of pixels, a corresponding lens part of the lens array is located.

6. A method of manufacturing a lens array including a plurality of lens parts arranged on a curved surface in a two-dimensional array, each of the plurality of lens parts including: a base part having a tapered side surface having an outer diameter that becomes smaller in a height direction away from the curved surface; and an apex part located on the base part and having a lens surface, wherein
each of the plurality of lens parts is formed by stacking a hardened layer formed by irradiating a photocrosslinkable material ejected from a molding head with light.

7. The method of manufacturing a lens array according to claim 6, wherein
the plurality of lens parts are formed by ejecting the photocrosslinkable material on the curved surface to stack the hardened layer.

8. The method of manufacturing a lens array according to claim 7, wherein
given a plurality of areas where the plurality of lens parts on the curved surface should be respectively formed, the hardened layer is formed in at least one of the plurality of areas while a normal direction of the curved surface in at least one of the plurality of areas and a direction of ejection of the photocrosslinkable material from the molding head intersect.

9. The method of manufacturing a lens array according to claim 7, wherein
given a plurality of areas where the plurality of lens parts on the curved surface should be respectively formed, the hardened layer is formed in each of the plurality of areas such that a normal direction of the curved surface in each of the plurality of areas and a direction of ejection of the photocrosslinkable material from the molding head are aligned, by changing an orientation of the curved surface.

10. The method of manufacturing a lens array according to claim 6, wherein
the base is curved after each of the plurality of lens parts is formed by stacking the hardened layer on a flat surface of the base.

11. The method of manufacturing a lens array according to claim 6, wherein
a frame provided at an outer circumference of the plurality of lens parts is formed by stacking the hardened layer.
